(19) United States
(12) Patent Application Publication
(10) Pub. No.: US 2008/0105924 A1
(43) Pub. Date: May 8, 2008

(54) SEMICONDUCTOR DEVICE AND METHOD FOR MANUFACTURING THE SAME

(76) Inventors: San-Jung Chang, Hsinchu City (TW); Yi-Mei Yang, Taipei City (TW)

Correspondence Address: HOLLAND & KNIGHT LLP, 10 ST. JAMES AVENUE, 11th Floor, BOSTON, MA, 02116-3889, US

(21) Appl. No.: 11/563,911

(22) Filed: Nov. 28, 2006

(30) Foreign Application Priority Data
Nov. 8, 2006 (TW) 095141397

(51) Int. Cl. H01L 29/78; H01L 21/00

(52) U.S. Cl. 257/347; 438/151; 257/E29.255; 257/E21.001

(57) ABSTRACT

A semiconductor device comprising a substrate, a gate structure disposed on the substrate, and a source/drain area disposed in the substrate is provided. The source/drain area comprises a silicon layer and a glass layer below the silicon layer, so as to define a shallow junction depth to avoid the possible short channel effect.

This application claims priorities to Taiwan Patent Application No. 095141397 filed on Nov. 8, 2006.

### CROSS-REFERENCES TO RELATED APPLICATIONS

Not applicable.

### FIELD OF THE INVENTION

The subject invention relates to a semiconductor device and its manufacturing method. Particularly, the subject invention relates to a transistor structure with a shallow junction depth at the source/drain and its manufacturing method.

### BACKGROUND OF THE INVENTION

Current electronic technology have been gearing towards the miniaturization of electronic equipments. Accordingly, the size of semiconductor devices should also be decreased. The channel length under the gate of a semiconductor transistor becomes shorter as the semiconductor device is reduced in size. However, the channel length cannot be reduced without any limitations. In fact, when the channel length is reduced to a certain level, it is very possible that short channel effects occur, resulting in transistor control problems. Also, hot electron effects occur due to the channel reductions and electric field enhancements so as to generate substrate currents, causing an electrical breakdown.

To resolve the problems resulting from the short channel effects, a recess channel array transistor or step transistor array has been developed to increase the current channel length. Moreover, the technology of lightly doped drain (LDD) has been provided. After forming the source/drain with a heavy doping level, a lightly doped area with a lightly doping level is formed beside the drain area to decrease the electric field in the channel and mitigate the hot electron effects (see Taiwan Patent Publication No. 1257175).

Furthermore, another approach for resolving the short channel effects is to reduce the junction depth of the source/drain. In this aspect, the ion implantation predominating the source/drain doping is critical to the reduction of the junction depth. However, the ion implantation cannot precisely control the depth of ion diffusion and often cannot achieve a shallow junction depth as desired.

To achieve a shallow junction depth, the subject invention provides a novel semiconductor device and its manufacturing method. The subject invention can effectively control the junction depth of the source/drain of the semiconductor device so as to avoid the short channel effects.

### SUMMARY OF THE INVENTION

One objective of the subject invention is to provide a semiconductor device comprising a substrate, a gate structure, and a source/drain area, wherein the source/drain area comprises a silicon layer and a glass layer below the silicon layer.

Another objective of the subject invention is to provide a method for manufacturing the above semiconductor device which comprises: providing a substrate; providing a gate structure on the substrate; forming a notch in a predetermined area located beside the gate structure and in the substrate; forming a glass layer in the notch; forming a silicon layer on the glass layer to fill the notch; and doping the predetermined area to form a source/drain area.

After reviewing the appended drawings and the conditions for carrying out the procedures as described below, persons having ordinary skill in the art can easily understand the basic spirit and other inventive objects of the subject invention as well as the technical means and preferred embodiments implemented for the subject invention.

### BRIEF DESCRIPTION OF THE DRAWINGS

FIG. 1 shows an embodiment of the semiconductor device of the subject invention, which is a transistor.

FIG. 2 shows a schematic drawing of the formation of a gate structure on a substrate.

FIG. 3 shows a schematic drawing of the formation of a notch beside the gate structure and in the substrate.

FIG. 4 shows a schematic drawing of the formation of a glass layer in the notch.

### DESCRIPTION OF THE INVENTION

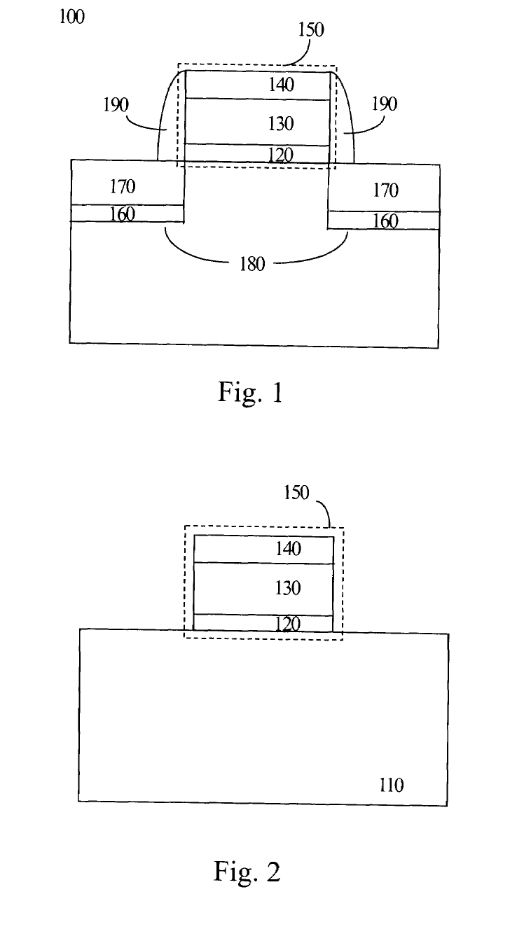

FIG. 1 shows a semiconductor device, specifically, a transistor 100, according to the subject invention. As shown in FIG. 1, the transistor 100 comprises a substrate 110 (e.g., a silicon substrate), a gate structure 150 disposed on the substrate 110, two source/drain areas 180 disposed both in the substrate 110 and the sides of the portion under the gate structure 150, and two spacers 190 disposed on the substrate 110 and the two sidewalls of the gate structure 150. It should be noted, as known by persons skilled in the art, that only one source/drain area 180 and one spacer 190 are required to exhibit the desired benefits of a transistor under proper arrangements. For convenience, it is described with the embodiment of two source/drain areas 180 and two spacers 190.

Generally, the gate structure 150 comprises a dielectric layer 120, a conductive layer 130, and a mask layer 140. The material of the dielectric layer 120 is well known by persons having ordinary skill in the art. The dielectric layer 120 is normally composed of an oxide layer, such as silicon oxide. The dielectric layer 130 is typically a polysilicon layer or a composite layer comprising two or more layers (such as a composite layer composed of a metal silicide, e.g., tungsten silicide, and a polysilicon layer). As for the mask layer 140, the material is silicon nitride in general.

Unlike conventional semiconductor devices, the source/drain area 180 of the transistor of the subject invention comprises a silicon layer 170 and a glass layer 160 below the silicon layer 170. The silicon layer 170 is provided for conducting a doping procedure and for serving as the source/drain after doping. The glass layer 160 is used as a barrier layer for blocking the penetration of the doping ion beam, so as to control the ion doped depth and avoid excessive ion diffusion. That is, the subject invention utilizes the glass layer 160 present in the source/drain area of the transistor to precisely define the desired shallow junction depth of the source/drain. Any proper glass materials can be used to provide the glass layer. The glass layer 160 can be provided from for example, but not limited to, a material selected from a group consisting of silicate, siloxane, silazane, and a combination thereof.

FIGS. 2 to 4 illustrates a method for manufacturing the semiconductor device of the subject invention (such as the transistor 100 depicted in FIG. 1). As shown in FIG. 2, a substrate 110 is provided and then a gate structure 150 is provided on the substrate 110. According to the well known technology in the semiconductor processing field, a dielectric layer 120, a conductive layer 130, and a mask layer 140 is sequentially formed on the substrate 110 to form a gate structure 150. The gate structure 150 can be formed in accordance with, but not limited to, the following procedures. An oxide layer is formed by thermal oxidization to service as the dielectric layer 120. Thereafter, a polysilicon layer is formed from the thermo-decomposition of silane by low pressure chemical vapor deposition, to serve as the conductive layer 130. Lastly, a silicon nitride layer for use as the mask layer 140 is formed on the conductive layer 130. As mentioned above, the conductive layer 130 can also be a composite layer comprising a polysilicon layer and a metal silicide layer (such as tungsten silicide). Using the tungsten silicide layer as an example, the metal silicide layer can be deposited by reacting tungsten hexafluoride and silane using low pressure chemical vapor deposition. Moreover, prior to forming the mask layer 140, a rapid thermal oxidization is optionally conducted to repair the conductive layer 130 and form an oxide layer (not depicted) on each side of the conductive layer 130 for protection.

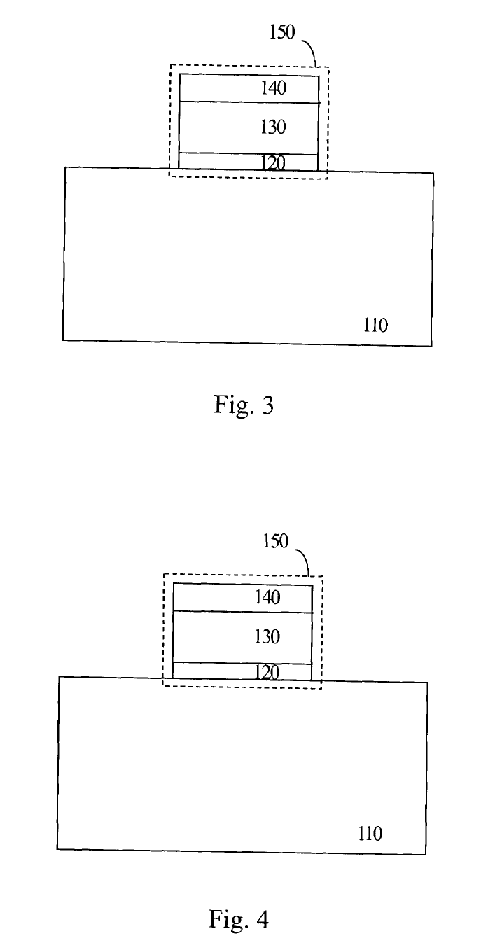

Then, as shown in FIG. 3, a notch 210 is formed in a predetermined area which is located beside the gate structure 150 and in the substrate 110. The formation can be achieved by such as, but not limited to, photolithography. In brief, a photoresist solution is used to provide a photoresist layer (not depicted) to cover the gate structure 150 and substrate 110. The photoresist solution is primarily formed by mixing a resin, a sensitizer, and a solvent. Then, a patterned mask (not depicted) is utilized to pattern the photoresist layer to expose a predetermined area located beside the gate structure 150 and on the substrate 110. Next, the patterned photoresist layer is used as an etching mask for forming a notch 210 with a predetermined depth in the predetermined area. Lastly, the photoresist layer is removed to form the substrate 110 with the notches 210 beside the gate structure 150. In this aspect, the embodiment depicted in FIG. 3 relates to two notches 210 formed on both sides of the gate structure 150. However, as mentioned above, the notch 210 can be optionally formed only on one side of the gate structure 150.

Optionally, according to the technology known in the semiconductor processing field, after the afore-mentioned photoresist mask etching step and before or after the removal of the photoresist layer, the sidewalls 220 of the notch 210 can be halo implanted to avoid the depletion region of the subsequently formed source/drain formed to affect the channels. The halo implantation of the sidewall 220 can be conducted with the use of such as, but not limited to, BF₂.

Referring to FIG. 3 in combination with FIG. 4, after forming the notch 210, a glass layer 160 is formed therein. According to one embodiment of the subject invention, a glass layer can first be formed to cover the gate structure 150, the substrate 110, and the notch 210. Thereafter, both the glass layer located above the gate structure 150 and the substrate 110 and a portion of the glass layer located in the notch 210 are etched, so as to maintain a thickness less than the predetermined depth of the notch 210 in the glass layer 160.

Preferably, the glass layer 160 is formed by spin coating, That is, a spin on glass layer is provided. The glass layer 160 can be formed in accordance with, but not limited to, the following procedures. A mixed solution comprising a glass material and an organic solvent (such as alcohols and ketones) is coated by a spin manner on the substrate 110, the gate structure 150, and the notch 210. Afterwards, baking is conducted to remove the solvent ingredient. followed by annealing to cure the glass material, remove any undesired ingredients, and stabilize its crystalline structure. The baking step can be performed at a temperature of about 75° C. to 400° C., while the annealing temperature can be performed at about 700° C. or higher. The relevant preparation procedures of the spin on glass layer can be found in the disclosures of U.S. Pat. No. 6,649,503 B2, which is incorporated hereinto for reference.

Next, a silicon layer 170 is formed on the glass layer 160 to fill the notch 210. Preferably, the silicon layer 170 is formed by selective epitaxial growth. The silicon layer 170 is then doped using ion implantation to form a source/drain therein. Moreover, another lightly doped drain can be processed to mitigate the influences of the “hot electron effects.” Lastly, spacers 190 are formed on the sidewalls of the gate structure 150 to complete the transistor 100 as shown in FIG. 1.

As described above, the subject invention utilizes a glass material to first form a glass layer in the substrate for use as a barrier layer for blocking the penetration of doping ion beams. Thus, a desired shallow junction depth of the source/drain of the semiconductor device (i.e., the depth of the silicon layer 170 shown in FIG. 1) is defined. As a result, the difficulty of controlling the ion diffusion depth during the formation of a source/drain area in the prior art is avoided.

The above examples are intended to illustrate the embodiments of the subject invention and explicate its technical features only, but not to limit the scope of protection of the subject invention. Any modifications or equal replacements that can be easily accomplished by persons skilled in this field belong to the scope claimed by the subject invention. The scope of protection of the subject invention should be on the basis of the following claims as appended.

What is claimed is:

1. A semiconductor device, comprising
a substrate;
a gate structure disposed on the substrate; and
a source/drain area disposed in the substrate;
wherein the source/drain area comprises a silicon layer and a glass layer below the silicon layer.

2. The semiconductor device of claim 1, wherein the silicon layer is provided by selective epitaxial growth.

3. The semiconductor device of claim 1, wherein the material of the glass layer is selected from a group consisting of silicate, siloxane, silazane, and a combination thereof.

4. The semiconductor device of claim 1, wherein the gate structure comprises a mask layer, a conductive layer, and a dielectric layer.

5. The semiconductor device of claim 4, wherein the conductive layer is a composite layer comprising a metal silicide layer and a polysilicon layer.

6. The semiconductor device of claim 4, wherein the mask layer is a silicon nitride layer.

7. The semiconductor device of claim 1, further comprising an insulation spacer on a sidewall of the gate structure.

8. A method for manufacturing the semiconductor device, comprising:
providing a substrate;
providing a gate structure on the substrate;
forming a notch in a predetermined area beside the gate structure and in the substrate;
forming a glass layer in the notch;
forming a silicon layer on the glass layer to fill the notch; and
doping the predetermined area to form a source/drain.

9. The method of claim 8, wherein the step of forming a notch in a predetermined area beside the gate structure and in the substrate comprises: providing a photoresist layer to cover the gate structure and the substrate; patterning the photoresist layer to expose a predetermined area located beside the gate structure and on the substrate;
conducting etching by using the patterned photoresist layer as a mask to form a notch with a predetermined depth in the predetermined area; and
removing the photoresist layer.

10. The method of claim 8, wherein after the step of forming a notch in a predetermined area beside the gate structure and in the substrate, the method further comprises halo implanting a sidewall of the notch.

11. The method of claim 8, wherein the step of forming a glass layer in the notch comprises:
forming a glass layer to cover the gate structure, the substrate, and the notch; and
etching the glass layer to remove the glass layer located upper the gate structure and the substrate and a portion of the glass layer located in the notch and to maintain in the notch a glass layer with a thickness less than the predetermined depth.

12. The method of claim 11, wherein the step of forming a glass layer to cover the gate structure, the substrate, and the notch comprises:
spin coating a glass material to form a glass material layer which covers the gate structure, the substrate, and the notch;
baking the spin on glass material layer; and
annealing the spin on glass material layer to form a glass layer.

13. The method of claim 8, wherein the material of the glass layer is selected from a group consisting of silicate, siloxane, silazane, and a combination thereof.

14. The method of claim 8, wherein the step of forming a silicon layer on the glass layer to fill the notch utilizes selective epitaxial growth to form the silicon layer.

15. The method of claim 8, wherein after the step of doping the predetermined area to form a source/drain, the method further comprises forming an insulation spacer on a sidewall of the gate structure.
